(19) United States
(12) Patent Application Publication
(10) Pub. No.: US 2025/0215296 A1
(43) Pub. Date: Jul. 3, 2025

(54) NEGATIVELY CHARGED SILICA PARTICLES, METHOD OF PRODUCING SUCH PARTICLES, COMPOSITIONS COMPRISING SUCH PARTICLES, AND A METHOD OF CHEMICAL-MECHANICAL POLISHING USING SUCH PARTICLES

(71) Applicant: MERCK PATENT GMBH, Darmstadt (DE)

(72) Inventors: Eric JACQUINOT, Trosly Breuil (FR); Frederic GUILLAUD, Trosly Breuil (FR)

(73) Assignee: MERCK PATENT GMBH, Darmstadt (DE)

(21) Appl. No.: 18/848,961

(22) PCT Filed: Mar. 20, 2023
(86) PCT No.: PCT/EP2023/056981

§ 371 Date: Sep. 20, 2024

(30) Foreign Application Priority Data
Mar. 22, 2022 (EP) 22305336.4

(51) Int. Cl. C09K 3/14; H01L 21/3105; H01L 21/321

(52) U.S. Cl. CPC C09K 3/1463; C09K 3/1436; H01L 21/31053; H01L 21/3212

(57) ABSTRACT

The present application relates to negatively charged silica particles, to a method of producing such particles, and to compositions comprising such particles as well as to a method for chemical mechanical polishing.

### TECHNICAL FIELD

The present application relates to negatively charged silica particles, to a method of producing such particles, and to compositions comprising such particles as well as to a method for chemical mechanical polishing.

### BACKGROUND

Modern semiconductor devices, memory devices, integrated circuits, and the likes comprise alternating sequences of conductive layers, semiconductive layers, and dielectric (or insulating) layers, with the dielectric layers insulating the conductive layers from one another. Connections between conductive layers may be established, for example, by metal vias. In producing such devices conductive, semiconductive, and/or dielectric materials are consecutively deposited onto and in part again removed from an underlying substrate on a semiconductive wafer.

With such devices becoming ever smaller, the accuracy of deposition and the thickness of the various layers become ever more important for ensuring that the so-produced devices perform according to expectation. It is therefore important to have planar surfaces, onto which the subsequent layer is to be deposited. As the required planarity cannot be achieved by deposition, the wafer (respectively the device to be produced) needs to be planarized by removing part or in some instances even all of such layer.

Chemical-mechanical polishing (CMP) is a widely used method for planarizing or removing part or all of a layer in the process of producing semiconductor devices and the likes. In the CMP process, an abrasive and/or a corrosive chemical slurry, such as for example a slurry of silica particles, is/are used together with a polishing pad. Pad and substrate or surface, e.g. a wafer, are pressed together and generally rotated non-concentrically, i.e. with different rotational axes, thereby abrading and removing material from the surface or substrate.

Chemical-mechanical polishing may be used to polish a wide range of materials used in semiconductor etc. manufacturing, such as metals and metal alloys (such as, for example, aluminum, copper or tungsten), metal oxides, silicon dioxide, or even polymeric materials. For each material, the polishing slurry needs to be specifically formulated so as to optimize its performance.

As is already indicated by the term “chemical-mechanical polishing”, the polishing is essentially done by a combination of mechanical polishing and chemical corrosion. Consequently, the silica particles used as abrasives in such a process not only need to be mechanically robust but also need to show certain properties and fulfill specific requirements so as to be fully compatible as component of a performant CMP slurry. For example, the composition of the silica particles needs to be modified depending on whether the particles need to be anionic or cationic.

It is known to make silica particles with negatively charged surface by modifying the silica surface with aluminate ions (see R. K. Iler, “The Chemistry of Silica: Solubility, Polymerization, Colloid and Surface Properties and Biochemistry of Silica”, Wiley, 1979, pages 407-409). However, it has been found that such surface modified silica particles show a high tendency to lose aluminum from the surface, thereby rendering it difficult to target a specific concentration of aluminum and consequently a specific charge, such meeting of targets being critical for efficient and reproducible performance in chemical-mechanical polishing.

From U.S. Pat. No. 4,217,240 homogeneous amorphous aluminosilicate particles and core-shell particles with an aluminosilicate coating as well as the production of such particles in dry form are known. With their high ratio of Si/Al of 1:1 to 19:1 the resulting particles are suitable for the intended use as porous catalyst powders but are unsuitable for chemical-mechanical polishing.

M.-S. Tsai and W.-C. Wu in Materials Letters 58 (2004) 1881-1884 disclose negatively charged colloidal silica in acid range formed by the addition of Al ions in form of Al(NO₃)₃ with active silicic acid to silica particle seed during the process of surface growth. However, the observed precipitation of Al(OH)₃ may render it challenging to target a specific aluminum content and consequently a specific negative charge in the resulting particles.

It is furthermore not disclosed in any of these documents that such negatively charged aluminum-comprising silica particles may be useful in chemical-mechanical polishing.

Thus, for improved efficiency of the production process there is still a need in industry to provide silica particles allowing for good removal rate selectivity between conductive and/or semiconductive materials on the one hand, and dielectric materials on the other hand.

The present application therefore aims at providing silica particles and compositions comprising such silica particles allowing for good selectivity between one or more conductive layer, which may comprise any one or more of metal, metal alloy, polysilicon, and any other suitable material, and one or more dielectric layer, preferably in such a way that the removal rate for dielectric materials is significantly lower than for metals and metal alloys, particularly tungsten.

### SUMMARY

The present inventors have now surprisingly found that one or more of the above-mentioned objects can be attained by the composition and methods as described herein.

The present application therefore provides for a composition comprising water and core-shell silica particles, wherein the composition is acidic, and the core-shell silica particles comprise a core and a shell, said shell comprising aluminate moieties internal to an outer surface of the silica particles.

The present application also provides for a method for producing such composition, the method comprising the steps of
(a) providing silica particles;
(b) providing an aqueous solution of silicic acid and providing an aqueous solution of sodium aluminate, and reacting in presence of the silica particles provided in the preceding step the silicic acid and the sodium aluminate under alkaline conditions and at a temperature of at least 40° C., to form a shell onto said silica particles, thereby producing core-shell silica particles; and
(c) passing the core-shell silica particles produced in the preceding step through a column of cation exchange resin,
thereby obtaining said composition.

Additionally, the present application provides for a method for chemical mechanical polishing comprising the steps of
(A) providing a substrate to be polished;
(B) providing said composition;
(C) providing a chemical mechanical polishing pad with a polishing surface;
(D) bringing the polishing surface of the chemical mechanical polishing pad into contact with the substrate; and
(E) polishing the substrate such that at least a part of the substrate is removed

### DETAILED DESCRIPTION

As used herein, “Me” denotes a methyl group (CH₃), and “Et” denotes an ethyl group (CH₂—CH₃).

As used herein, the term “water glass” is used to generally denote alkali salts, preferably sodium and potassium salts, of silicic acid Si(OH)₄. The respective sodium and potassium salts may, for example, be represented by the formula M₂ₓSi_{y}O_{2y+x} or (M₂O)ₓ·(SiO₂)_{y}, with M=Na or K and, for example, x=1 and y being an integer of from 2 to 4.

As used herein, the term “water glass-based” is used to denote that the present silica particles are preferably produced from such alkali salts of silicic acid as starting material.

As used herein, the term “TMOS/TEOS-based” is used to generally denote silica particles that have been produced using Si(OMe)₄ (“TMOS”) and/or Si(OEt)₄ (“TEOS”) as starting material.

As used herein, the term “silicate” is used to denote salts and esters of ortho-silicic acid (Si(OH)₄), which throughout this application may also be referred to as “silicic acid”, and its condensation products. It is also noted that a gel or a solution of silicic acid is understood to generally also comprise condensates of silicic acid.

As used herein, the term “aluminate” is first used to denote tetrahydroxy aluminate, which may be represented as [Al(OH)₄]. When incorporated into a silica particle, the term “aluminate”, for example as used in “aluminate moiety” or “aluminate comprising shell”, is used to denote a chemical group, which may be represented as [Al(—O—)₄]. Without wishing to be bound by theory, it is believed that therein the three outer electrons of the aluminium have been removed, it thereby becoming an Al³⁺ ion, with —O— serving as bridge to a neighboring aluminum or silicon, or alternatively being “filled”, preferably with a proton or an alkali metal ion (preferably Na⁺ or K⁺).

As used herein, the term “colloidal” is used to denote particles dispersed in a medium having at least in one direction a dimension between 1 nm and 1 μm (see also Compendium of Chemical Terminology, Gold Book, International Union of Pure and Applied Chemistry, Version 2.3.3, 2014 Feb. 24, page 295).

As used herein, the term “point of use” denotes the chemical-mechanical polishing process. For example, the expression “composition at point of use” is used to denote the composition as used in the chemical-mechanical polishing process.

Generally, silica particles, for example water glass-based colloidal silica particles, may be obtained in a wet process from above described starting materials as is well known to the person skilled in the art and, for example, disclosed in R. K. Iler, “The Chemistry of Silica: Solubility, Polymerization, Colloid and Surface Properties and Biochemistry of Silica”, Wiley, 1979. For producing the present silica particles comprised in the present silica slurry, it is preferred that the silica particles are obtained in a wet process from an alkaline silicate.

Though the present invention will be explained by example of water glass-based colloidal silica particles, the actual type of particles is not particularly limited. Thus, the silica particles used herein may, for example, be any type of colloidal silica particles. The present silica particles may have been produced from any suitable starting material, and may, for example, be water glass-based or TMOS/TEOS-based. However, preferably the silica particles used herein are colloidal silica particles, and may be water-glass based.

In general terms, the present application relates to a composition comprising water and core-shell silica particles, said composition being acidic.

The present composition is acidic. Preferably, it has a pH of at least 1.5. Preferably, it has a pH of at most 5.5, more preferably of at most 5.0, even more preferably of at most 4.5, still even more preferably of at most 4.0, and most preferably of at most 3.5.

The present composition preferably has a zeta potential of at most 0 mV. Preferably, the present composition has a zeta potential of at least −30 mV. Thus, the zeta potential of the present particles is preferably in the range of from 0 mV to −30 mV. The zeta potential may be determined as described in the Examples.

The present core-shell silica particles may be comprised in the present composition in at least 0.1 wt % and in at most 50 wt %, with wt % relative to the total weight of the composition. The specific choice of the content of core-shell silica particles in the present composition may, for example, depend on whether the composition is supplied as a concentrate, for example for transport, or when actually used at the point of use.

If supplied as a concentrate, which may then be diluted with water, preferably deionized water, prior to its use in a chemical mechanical polishing process, the present composition may comprise the present core-shell silica particles in up to and including 50 wt %, for example, in up to and including 25 wt %, or in up to and including 30 wt %, or in up to and including 35 wt %, or in up to and including 40 wt %, with wt % relative to the total weight of the present composition.

Alternatively, at the point of use, i.e. when used in a chemical mechanical polishing process, the present composition preferably comprises the present core-shell silica particles in at least 0.1 wt % (for example in at least 0.2 wt % or 0.3 wt % or 0.4 wt %), more preferably in at least 0.5 wt %, even more preferably in at least 1.0 wt, still even more preferably in at least 1.5 wt %, and most preferably in at least 2.0 wt %, with wt % relative to the total weight of the present composition. In this case, the present composition preferably comprises the present core-shell silica particles in at most 10 wt %, more preferably in at most 5.0 wt %, even more preferably in at most 4.0 wt %, still even more preferably in at most 3.5 wt %, and most preferably in at most 3.0 wt %, with wt % relative to the total weight of the present composition.

The present core-shell silica particles comprise a core and a shell, but may also comprise two or more shells.

Such shell, and if two or more shells are present preferably the outermost shell, comprises aluminate moieties internal to an outer surface of the core-shell silica particles. Throughout this application, the term “aluminate-comprising shell” will be used to denote the shell comprising aluminate moieties.

Preferably, said aluminate-comprising shell has a thickness of at least 0.1 nm, more preferably of at least 0.15 nm, and most preferably of at least 0.2 nm. Preferably said aluminate-comprising shell has a thickness of at most 2.0 nm, more preferably of at most 1.8 nm, even more preferably of at most 1.6 nm or 1.4 nm, still even more preferably of at most 1.2 nm, and most preferably of at most 1.0 nm.

The amount of aluminum comprised in the aluminate-comprising shell may be adjusted so as to achieve the negative charge required for the targeted application. Such varying the aluminum content is well within the skills of the expert. It has, however, been found that the present core-shell silica particles are best suited for chemical-mechanical polishing if the amount of aluminum comprised in the aluminate-comprising shell is at least 500 ppm or 1,000 ppm, more preferably at least 2,000 ppm, even more preferably at least 3,000 ppm, still even more preferably at least 4,000 ppm and most preferably at least 5,000 ppm, with ppm relative to the total weight of the aluminate-comprising shell of the present core-shell silica particles. The amount of aluminum comprised in the aluminate-comprising shell preferably is at most 25,000 ppm, more preferably at most 20,000 ppm, even more preferably at most 15,000 ppm, and most preferably at most 10,000 ppm, with ppm relative to the total weight of the aluminate-comprising shell of the present core-shell silica particles.

Shape and dimensions of the silica particles used herein are not particularly limited, provided that such silica particles are suitable for use in CMP applications. Such silica particles may, for example, be spherical, oval, curved, bent, elongated, branched, or cocoon-shaped.

For spherical silica particles, the average diameter is preferably at least 5 nm, more preferably at least 10 nm, and most preferably at least 15 nm. For spherical particles, the average diameter is preferably at most 200 nm, more preferably at most 150 nm or 100 nm, even more preferably at most 90 nm or 80 nm or 70 nm or 60 nm, still even more preferably at most 50 nm or 45 nm or 40 nm or 35 nm or 30 nm, and most preferably at most 25 nm. For example, particularly preferred silica particles have an average diameter of at least 15 nm and of at most 25 nm.

For elongated, curved, bent, branched, and oval silica particles their average diameter is preferably as described above for spherical colloidal silica particles. Preferably, such elongated or oval colloidal silica particles have an aspect ratio, i.e. the ratio of length to average diameter, of at least 1.1, more preferably of at least 1.2 or 1.3 or 1.4 or 1.5, even more preferably at least 1.6 or 1.7 or 1.8 or 1.9, and most preferably at least 2.0. Said aspect ratio is preferably at most 10, more preferably at most 9 or 8 or 7 or 6, and most preferably at most 5.

Generally, the present core-shell silica particles may be produced by standard methods. In a first step, silica particles are provided, which subsequently are to form the core of the present core-shell silica particles. Thus, the present method for producing a composition comprising water and core-shell silica particles, especially for producing the present core-shell silica particles, comprises the step of
(a) providing silica particles.

In step (a), these silica particles may be provided either by producing them in situ through the polycondensation of silicic acid, or alternatively by providing so-called “seed particles”. Such seed particles are silica particles, preferably colloidal silica particles, such as water-glass based colloidal silica particles, being of smaller size (for example, smaller diameter) than the targeted size of the present core-shell silica particles. These seed particles may then either be used directly as seed particles in subsequent step (b), or alternatively, a shell of silica may be deposited onto such seed particles by polycondensing silicic acid onto their surface until the desired particle size has been reached, which resulting particles may then be used as seed particles for the subsequent step (b).

It is noted that the silica particles provided in step (a), whether produced in situ or alternatively provided as seed particles, are preferably silica particles obtained through the polycondensation of silicic acid alone, which could also be referred to as silica particles obtained through a “homo-polycondensation of silicic acid”.

In subsequent step (b), the aluminate-comprising shell is formed by reacting an aqueous solution of silicic acid with an aqueous solution of an aluminate salt, preferably sodium aluminate. Thus, the present method for producing a composition comprising water and core-shell silica particles, especially for producing the present core-shell silica particles, comprises the step of
(b) providing an aqueous solution of silicic acid and providing an aqueous solution of an aluminate salt, preferably an aqueous solution of sodium aluminate, and reacting in presence of the silica particles provided in preceding step (a) to form a shell (notably an aluminate-comprising shell) onto said silica particles provided in preceding step (a), thereby producing the core-shell silica particles as defined herein.

The reaction (or polycondensation) of silicic acid and the aluminate in step (b) is done at alkaline conditions, preferably at a pH of at least 8, more preferably at a pH of at least 9, and most preferably of at least 10.

It is noted that, in fact, step (b) is a co-condensation of silicic acid and aluminate (i.e. tetrahydroxy aluminate), thereby producing what may be referred to as a co-condensate. Without wishing to be bound by theory, it is believed that the distribution of aluminum and silicon in such co-condensate is random. By contrast, a surface modification of a silica particle with an aluminate would rather result in a layer consisting of aluminate moieties on top.

In case the pH needs to be adjusted by rendering more basic, such adjustment may be done by adding a base. Such base may be any suitable base. It is, however, preferred that such base is selected from the group consisting of potassium hydroxide, sodium hydroxide, lithium hydroxide, cesium hydroxide, rubidium hydroxide, ammonia, organic amines, and any blend of any of these. Of these, potassium hydroxide and ammonia are particularly preferred.

Suitable organic amines may be selected from the group consisting of alkyl amines, alkanol amines, and any blend of these, with alkanol amines being preferred.

Examples of suitable alkyl amines may be represented by the following formula (I)

H₃₋ₐNR¹ₐ (1)
wherein a is an integer at each occurrence independently selected from the group consisting of 1, 2, and 3; and R¹ is an alkyl group having 1, 2, or 3 carbon atoms. Preferred alkyl amines may be selected from the group consisting of methylamine (H₂NMe), dimethylamine (HNMe₂), trimethylamine (Nme₃), ethylamine (H₂Net), diethylamine (HNEt₂), triethylamine (Net₃), and any blend of any of these.

Examples of suitable alkanol amines may be represented by the following formula (II)

H₂N—R²—OH (II)
wherein R² is at each occurrence independently an alkanediyl having at least one and at most five carbon atoms. Thus, R² may at each occurrence independently be selected from the group consisting of methylene (—CH₂—), ethanediyl (—CH₂—CH₂—), propanediyl (—(CH₂—)₃), butanediyl (—(CH₂—)₄), and pentanediy (—(CH₂—)₅).

Preferred alkanol amines may be selected from the group consisting of 2-amino ethanol, 3-amino propanol, and 4-amino butanol, with 2-amino ethanol being most preferred.

The reaction (or polycondensation) of silicic acid and the aluminate in step (b) is done at a temperature of at least 40° C., preferably of at least 50° C. or 60° C.

The molar ratio of aluminum to silicon in step (b) may be appropriately adjusted so as to arrive at the targeted aluminum content in the aluminate-comprising shell of the present core-shell silica particles as described herein. Preferably, the molar ratio of aluminum to silicon in step (b) is selected such that the aluminate-comprising shell comprises aluminum in the amount as defined above. Such selection is well within the expertise of the skilled person and—also in view of the further information provided by the Examples—does not require extensive experimentation. As a non-limiting example, the molar ratio of aluminum to silicon (Al:Si) in step (b) may, for example, be at least 0.001 and at most 0.10, preferably at most 0.09.

The so-obtained core-shell silica particles from step (b) are then passed through a column of cation exchange resin. The present method for producing a composition comprising water and core-shell silica particles, especially for producing the present core-shell silica particles, comprises the step of
(c) passing the core-shell silica particles produced in the preceding step through a column of cation exchange resin,
thereby obtaining the composition as defined above.

The present core-shell silica particles may optionally comprise an alkoxy organosilane on the surface. Preferably, such alkoxy organosilane is hydrophilic.

The alkoxy organosilane used herein preferably is a poly(alkoxy) organosilane. More preferably, said alkoxy organosilane is of the following formula (III)

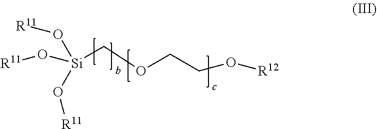

wherein
R¹¹ and R¹² are at each occurrence independently of each other selected from the group consisting of methyl, ethyl and propyl;
b is an integer of at least 1 and at most 5; and
C is an integer of at least 1 and at most 30, preferably at most 25, and even more preferably at most 20.

Preferred examples of alkoxy organosilanes of formula (III) are those, wherein R¹¹ and R¹² are all Me or Et, b is 3, and c is at least 6 and at most 12. For example, c may be at least 6 and at most 9, or at least 9 and at most 12, or at least 8 and at most 12.

Most preferably, the alkoxy organosilane used herein is one of formula (III), wherein R¹¹ and R¹² are all methyl, b is 3, and c is 11.

Such alkoxy organosilanes may, for example, be obtained from Momentive Performance Materials, Albany, NY, USA.

Preferably, the alkoxy organosilane as defined herein is reacted with the present silica particles in a weight ratio of alkoxy organosilane to silica particles of at least 0.001, more preferably of at least 0.005, even more preferably of at least 0.010, still even more preferably of at least 0.015, and most preferably of at least 0.020.

Preferably, the alkoxy organosilane as defined herein is reacted with the present silica particles in a weight ratio of alkoxy organosilane to silica particles of at most 0.50, more preferably of at most 0.40 or 0.30, even more preferably of at most 0.20, still even more preferably of at most 0.15 or 0.10, and most preferably of at most 0.050.

Alkoxy organosilane-modified silica particles may be produced by a process comprising the steps of
(1) providing an aqueous dispersion of core-shell silica particles as defined above, and
(2) providing an alkoxy organosilane as defined above.

Because for this, it is necessary that the aqueous dispersion of the silica particles is acidic, the present method of producing alkoxy organosilane-modified silica particles also comprises the step of
(3) rendering the aqueous dispersion of silica particles acidic if it is not already acidic, and preferably adjusting the pH for the aqueous dispersion to have a pH of at least 1.0, more preferably of at least 2.0, and a pH of at most 5.0, more preferably of at most 4.0.

In the following the now acidic aqueous dispersion of silica particles and the alkoxy organosilane as defined herein are brought into contact with each other, thereby obtaining the alkoxy organosilane-modified silica particles. This may be done simply by mixing the acidic aqueous dispersion of silica particles and the alkoxy organosilane, and optionally stirring for a certain amount of time, possibly at elevated temperatures.

Thus, the present method comprises the step of
(4) then bringing the silica particles and the alkoxy organosilane into contact with each other, thereby obtaining the alkoxy organosilane-modified silica particles.

It may, however, also be preferable that the present core-shell silica particles do not comprise an alkoxy organosilane as defined herein.

Optionally, the present composition further comprises any one or more of the group consisting of biocide, pH-adjusting agent, pH-buffering agent, oxidizing agent, chelating agent, corrosion inhibitor, and surfactant.

Such oxidizing agent may be any suitable oxidizing agent for the one or more metal or metal alloy of the substrate to be polished using the present composition. For example, the oxidizing agent may be selected from the group consisting of bromates, bromites, chlorates, chlorites, hydrogen peroxide, hypochlorites, iodates, monoperoxy sulfate, monoperoxy sulfite, monoperoxy phosphate, monoperoxy hypophosphate, monoperoxy pyrophosphate, organo-halo-oxy compounds, periodates, permanganate, peroxyacetic acid, ferric nitrates, and any blend of any of these. Such oxidizing agent may be added to the present composition in a suitable amount, for example, in at least 0.1 wt % and at most 6.0 wt %, with wt % relative to the total weight of the present composition at point of use.

Such corrosion inhibitor, which may, for example, be a film forming agent, may be any suitable corrosion inhibitor. For example, the corrosion inhibitor may be glycine, which may be added in an amount of at least 0.001 wt % to 3.0 wt %, with wt % relative to the total weight of the present composition at point of use.

Such chelating agent may be any suitable chelating or complexing agent for increasing the removal rate of the respective materials, preferably metal or metal alloy, to be removed, or alternatively or in combination for capturing trace metal contaminants that may unfavorably influence performance in the polishing process or in the finished device. For example, the chelating agent may be compounds comprising one or more functional groups comprising oxygen (such as carbonyl groups, carboxyl groups, hydroxyl groups) or nitrogen (such as amine groups or nitrates). Examples of suitable chelating agents include, in a non-limiting way, acetylacetonates, acetates, aryl carboxylates, glycolates, lactates, gluconates, gallic acid, oxalates, phthalates, citrates, succinates, tartrates, malates, ethylenediaminetetraacetic acid and salts thereof, ethylene glycol, pyrogallol, phosphonates, ammonia, amino alcohols, di- and tri-amines, nitrates (e.g. ferric nitrates), and any blend of any of these.

Such biocide may be selected from any suitable biocide, for example, from isothiazolin derivative-comprising biocides. Such biocide is generally added in an amount of at least 1 ppm and of at most 100 ppm, with ppm relative to the total weight of the present composition at point of use. The amount of biocide added may be adapted depending, for example, upon the composition and planned storage period.

Such pH-adjusting agent may be selected from suitable acids, such as hydrochloric acid, nitric acid or sulfuric acid, with nitric acid or sulfuric acid being preferred, and with nitric acid being particularly preferred.

Such surfactant may be selected from any suitable surfactant, such as cationic, anionic and non-ionic surfactants. A particularly preferred example is an ethylenediamine polyoxyethylene surfactant. Generally, surfactants may be added in an amount of from 100 ppm to 1 wt %, with ppm and wt % relative to the total weight of the present composition at point of use.

Some of these compounds may exist in form of a salt, such as a metal salt, acid, or as a partial salt. Equally, some of these compounds may fulfill more than one function if comprised in a composition suitable for chemical mechanical polishing. For example, ferric nitrates, particularly Fe(NO₃)₃, may act as chelating agent and/or oxidizing agent and/or catalyst agent.

A particularly preferred example of a composition at point of use that may be used herein comprises
(i) at least 1.0 wt % and at most 4.0 wt % of surface-modified silica particles as defined herein,
(ii) at least 0.001 wt % and at most 0.10 wt %, preferably at least 0.01 wt % and at most 0.05 wt % of Fe(NO₃)₃,
(iii) at least 10 ppm and at most 100 ppm of Kathon ICP II biocide,
(iv) optionally at least 0.01 wt % and at most 0.05 wt % of malonic acid,
(v) at least 1.0 wt % and at most 8.0 wt % of hydrogen peroxide (H₂O₂), and
(vi) water in such an amount to bring the total up to 100 wt %,
with ppm and wt % relative to the total weight of the composition at point of use.

The present composition may be prepared by standard methods, well known to the person skilled in the art. Generally such preparation involves mixing and stirring phases. It can be performed either in continuous manner or batchwise.

The composition as described above may be used in a chemical mechanical polishing (CMP) process, wherein a substrate is polished. Thus, in general terms the present application also provides for a method for chemical-mechanical polishing comprising the steps of
(A) providing a substrate to be polished; and
(B) providing the composition as described herein.

The substrate to be polished in the present CMP process comprises (i) at least one layer comprising, preferably essentially consisting of, silicon oxide, or at least one layer comprising, preferably essentially consisting of, silicon nitride, and (ii) at least one layer comprising, preferably essentially consisting of one or more metal or metal alloy. The present method for chemical mechanical polishing therefore comprises the following steps of
(A) providing a substrate comprising (i) at least one layer comprising, preferably essentially consisting of, silicon oxide; and, preferably thereon, (ii) at least one layer comprising, preferably essentially consisting of, one or more metal or metal alloy; and
(B) providing the composition as defined herein.

As used herein, the term “thereon” is used to indicate that the metal or metal alloy-comprising layer is essentially placed/located on top of the silicon oxide-comprising layer or silicon nitride-comprising layer. Expressed differently, and with respect to the chemical mechanical polishing, the layer on top is the layer that before starting to polish is in closer proximity to the polishing pad mounted on the CMP polisher.

As used herein, the term “essentially consisting of” is used to denote that such layer may comprise a minor amount of a different material, for example, in an amount of at most 5 wt % (for example in an amount of at most 4 wt % or 3 wt % or 2 wt % or 1 wt % or 0.5 wt % or 0.1 wt %), with wt % relative to the total weight of such layer.

Preferably, said silicon oxide comprised in the layer, which is in turn comprised in the substrate, may be selected from the group consisting of borophosphosilicate glass (BPSG), plasma-enhanced tetraethyl ortho silicate (PETEOS), thermal oxide, undoped silicate glass, high density plasma (HDP) oxide, and silane oxide.

Preferably, said metal or metal alloy comprised in the layer, which is in turn comprised in the substrate, may be selected from the group consisting of tungsten, tantalum, copper, titanium, titanium nitride, aluminum silicon, and any combination of any of these, and preferably is tungsten.

In the CMP-process a polishing pad with a polishing surface is used for the actual polishing of the substrate. Such polishing pad may, for example, be a woven or non-woven polishing pad, and comprise or essentially consist of a suitable polymer. Exemplary polymers include polyvinylchloride, polyvinylfluoride, nylon, poly-propylene, polyurethane, and any blend of these, to only name a few. Polishing pad and the to be polished substrate are generally mounted on a polishing apparatus, pressed together, and generally rotated non-concentrically, i.e. with different rotational axes, thereby abrading and removing material from the surface or substrate. Thus, the present CMP process further comprises the steps of
(C) providing a chemical mechanical polishing pad with a polishing surface;
(D) bringing the polishing surface of the chemical mechanical polishing pad into contact with the substrate; and
(E) polishing the substrate such that at least a part of the substrate is removed.

The present CMP process may be applied in the production of flat panel displays, integrated circuits (ICs), memory or rigid disks, metals, interlayer dielectric devices (ILDs), semiconductors, micro-electro-mechanical systems, ferroelectrics, and magnetic heads. In other words, the substrate to be polished in the present CMP process may be selected from the group consisting of flat panel displays, integrated circuits (ICs), memory or rigid disks, metals, interlayer dielectric devices (ILDs), semiconductors, micro-electro-mechanical systems, ferroelectrics, and magnetic heads.

### EXAMPLES

All of the materials used in the present examples are commercially available from well-known sources. Sodium aluminate (CAS-no. 11138-49-1) may, for example, be obtained from Sigma-Aldrich, a subsidiary of Merck KGaA, Darmstadt, Germany. Water glass-based silica particles were obtained internally from Merck KGaA, Darmstadt, Germany, and are commercially available under the Klebosol® tradename. Silicic acid was obtained internally as an aqueous solution with an SiO₂ content of ca. 6 wt %, with wt % relative to the total weight of the aqueous solution. Cation exchange resin used was AMBERJET™ 1200 H, supplied by Rohm and Haas Company, Philadelphia, Pennsylvania, USA.

All water used in the examples was de-ionized.

Indicated particle sizes are the z-average particle sizes as determined either on basis of the specific surface area (SSA) or calculated on basis of the mass of silica introduced during the synthesis.

Specific surface areas (SSA) were determined as disclosed in G. W. Sears Jr., Anal. Chem. 1956, 28 (12), 1981-1983 by titration with aqueous sodium hydroxide.

The zeta potential was determined by electrophoretic light scattering (ELS) in aqueous medium with the below-indicated properties using a Zetasizer Nano, obtained from Malvern Instruments Limited, Worcestershire, UK.

Aluminum content was determined by inductively coupled plasma atomic emission spectroscopy (ICP-OES) on an Agilent 700 ICP-OES, available from Agilent, Santa Clara, California, USA, using the manufacturer-defined standard conditions.

All wt % are relative to the total weight of the respective aqueous dispersion or solution, unless indicated otherwise.

### Example 1 (Comparative)

1776.8 g of an aqueous dispersion (pH=10.3) of 20.0 wt % of silica particles having an average particle diameter of 9 nm and a specific surface area of 300 m²/g were heated to boiling. Then 1633.4 g of aqueous silicic acid solution (5.81 wt % SiO₂) were added to the boiling aqueous dispersion of silica particles under agitation over a period of about two hours.

The resulting reaction mixture was kept agitated for a further 30 min at boiling temperature and then allowed to cool to room temperature, all the while being agitated, yielding 2259 g of an intermediate aqueous dispersion (IM-01) of 20.0 wt % of silica particles having an average diameter of 9.75 nm. Further properties of the intermediate aqueous dispersion (IM-01) are indicated in Table 1 below.

1070 g of the so-obtained intermediate aqueous dispersion (IM-01) of silica particles were passed through a column of cation exchange resin so that 904 g of an aqueous dispersion comprising 19.15 wt % of silica particles and having a pH of 2 to 3 were recovered. The so-recovered aqueous dispersion was further diluted with de-ionized water to give 1154 g of aqueous dispersion of 15 wt % of silica particles (D-01) having an average diameter of 9.75 nm. Properties of the resulting aqueous dispersion (D-01) are given in Table 2 below.

### Example 2 (Comparative)

1070 g of the intermediate aqueous dispersion (IM-01) of silica particles and an aqueous solution of sodium aluminate (3.634 g sodium aluminate in 115.3 g of water) were separately from each other heated to between 50° C. and 60° C. Then the aqueous solution of sodium aluminate was added to the intermediate aqueous dispersion (IM-01), heated to 70° C., and then kept under agitation over a period of about one hour.

The resulting reaction mixture was then allowed to cool to room temperature, all the while being agitated, yielding 1182 g of intermediate aqueous dispersion (IM-02) of 18.1 wt % of silica particles having an average diameter of 9.75 nm. Further properties of the intermediate aqueous dispersion (IM-01) are indicated in Table 1 below.

The so-obtained intermediate aqueous dispersion (IM-02) of silica particles was then passed through a column of cation exchange resin, and 956 g of an aqueous dispersion comprising 16.8 wt % of silica particles having a pH of 2 to 3 were recovered. The so-recovered aqueous dispersion of silica particles were then diluted to give 1072.5 g of an aqueous dispersion (D-02) of 15.0 wt % of silica particles having an average diameter of 9.75 nm. Properties of the resulting aqueous dispersion (D-02) are given in Table 2 below.

### Example 3

750 g of an aqueous dispersion of 35.5 wt % of silica particles having an average particle diameter of 9 nm with a pH of 10.2 were heated to boiling. Then 4.526 g of sodium aluminate in 578 ml of water and 1224.7 g of aqueous silicic acid solution (5.91 wt % SiO₂) were added in parallel to the boiling dispersion under agitation over a period of about two hours.

The resulting reaction mixture was kept agitated for a further 30 min and allowed to cool to room temperature while being agitated, yielding 1558 g of intermediate aqueous dispersion (IM-03) of 21.75 wt % of silica particles with aluminate-comprising shell having an average diameter of 9.75 nm. Further properties of the intermediate aqueous dispersion (IM-03) are indicated in Table 1 below.

The so-obtained intermediate aqueous dispersion (IM-03) of silica particles with aluminate-comprising shell was passed through a column of cation exchange resin, and 1165.2 g of aqueous dispersion of 21.75 wt % of silica particles with an aluminate-comprising shell and having a pH of 2 to 3 were recovered, and subsequently further diluted with de-ionized water to a total of 1689.5 g of aqueous dispersion (D-03) of 15.0 wt % of silica particles. Properties of the resulting aqueous dispersion (D-03) are given in Table 2 below.

### Example 4

750 g of an aqueous dispersion of 35.5 wt % of silica particles having an average particle diameter of 9 nm with a pH of 10.2 were heated to boiling. Then 9.052 g of sodium aluminate in 573.5 ml of water and 1245.5 g of aqueous silicic acid solution (5.81 wt % SiO₂) were added in parallel to the boiling dispersion under agitation over a period of about two hours.

The resulting reaction mixture was continued to be agitated for a further 30 min and allowed to cool to room temperature while being agitated, yielding 1376.3 g of intermediate aqueous dispersion (IM-04) of 24.6 wt % of silica particles with aluminate-comprising shell having a diameter of 9.75 nm. Further properties of the intermediate aqueous dispersion (IM-04) are indicated in Table 1 below.

The so-obtained intermediate aqueous dispersion (IM-04) of silica particles with aluminate-comprising shell was then passed through a column of cation exchange resin, and 1235 g of aqueous dispersion of 21.3 wt % of silica particle with aluminate-comprising shell and a pH of 2 to 3 were recovered and subsequently further diluted with de-ionized water to a total of 1753.7 g of aqueous dispersion (D-04) of 15.0 wt % of silica particles with an aluminate-comprising shell. Properties of the resulting aqueous dispersion (D-04) are given in Table 2 below.

TABLE 1
Properties of the intermediate dispersions
(measured at 15 wt % SiO₂)

| | | IM-01 | IM-02 | IM-03 | IM-04 |
|---|---|---|---|---|---|
| SiO₂ content | [wt %] | 15.0 | 15.0 | 15.0 | 15.0 |
| Average particle | [nm] | 9.75 | 9.75 | 9.75 | 9.75 |
| diameter | | | | | |
| pH (at 20° C.) | | 10.27 | 10.54 | 10.39 | 10.62 |
| Zeta potential | [mV] | −31.6 | −22.1 | −45.8 | −40.4 |
| Al content (ICP-OES) | [ppm] | 46 | 822 | 656 | 1253 |

TABLE 2
Properties of the aqueous dispersions (measured at 15 wt % SiO₂)

| | | D-01 | D-02 | D-03 | D-04 |
|---|---|---|---|---|---|
| SiO₂ content | [wt %] | 15.0 | 15.0 | 15.0 | 15.0 |
| Average particle | [nm] | 9.75 | 9.75 | 9.75 | 9.75 |
| diameter | | | | | |
| pH (at 20° C.) | | 2.80 | 2.67 | 2.59 | 2.51 |
| Zeta potential | [mV] | −5.1 | −14.2 | −17.6 | −19.6 |
| Al content (ICP-OES) | [ppm] | 45 | 217 | 375 | 654 |

The above results for the Zeta potential clearly show its becoming more negative with increasing concentration of aluminate comprised in the present particles.

### Example 5 (Comparative)

For a first batch, 1800 g of an aqueous dispersion (pH=9.2) of 35.3 wt % of silica particles having an average particle diameter of 35 nm and a specific surface area of 74.4 m²/g were heated to boiling. Then 710.3 g of aqueous silicic acid solution (5.87 wt % SiO₂) were added to the boiling aqueous dispersion of silica particles under agitation over a period of about two hours. The resulting reaction mixture was further kept agitated for a further 30 min at boiling temperature and then allowed to cool to room temperature, all the while being agitated.

For a second batch, 1800 g of the same dispersion of silica particles as used for the first batch above was heated to boiling. Then 716.6 g of aqueous silicic acid solution (5.82 wt % SiO₂) were added to the boiling aqueous dispersion of silica particles under agitation over a period of about two hours. The resulting reaction mixture was further kept agitated and then allowed to cool as done for the first batch.

The two batches were combined, yielding 3594 g of an intermediate aqueous dispersion (IM-05) of 32.2 wt % of silica particles having an average diameter of 35.75 nm. Further properties of the intermediate aqueous dispersion (IM-05) are indicated in Table 3 below.

1795 g of the so-obtained intermediate aqueous dispersion (IM-05) of silica particles were passed through a column of cation exchange resin so that 1613 g of an aqueous dispersion comprising 30.5 wt % of silica particles and having a pH of 2 to 3 were recovered. The so-recovered aqueous dispersion was further diluted with de-ionized water to give 1640 g of aqueous dispersion of 30.0 wt % of silica particles (D-05) having an average diameter of 35.75 nm. Properties of the resulting aqueous dispersion (D-05) are given in Table 4 below.

### Example 6 (Comparative)

1795 g of the intermediate aqueous dispersion (IM-05) of silica particles and an aqueous solution of sodium aluminate (2.508 g sodium aluminate in 129.1 g of water) were separately from each other heated to between 50° C. and 60° C. Then the aqueous solution of sodium aluminate was added to the intermediate aqueous dispersion (IM-05), heated to 70° C., and then kept under agitation over a period of about one hour.

The resulting reaction mixture was then allowed to cool to room temperature, all the while being agitated, yielding 1847.4 g of intermediate aqueous dispersion (IM-06) of wt % of silica particles having an average diameter of 35.75 nm. Further properties of the intermediate aqueous dispersion (IM-06) are indicated in Table 3 below.

The so-obtained intermediate aqueous dispersion (IM-06) of silica particles was then passed through a column of cation exchange resin, and 1728.4 g of an aqueous dispersion (D-06) comprising 29.7 wt % of silica particles having a pH of between 2 and 3 were recovered. Properties of the resulting aqueous dispersion (D-06) are given in Table 4 below.

### Example 7

1800 g of an aqueous dispersion of 33.6 wt % of silica particles having an average particle diameter of 35 nm with a pH of 9.2 were heated to boiling. Then 2.627 g of sodium aluminate in 215.8 ml of water and 699.2 g of aqueous silicic acid solution (5.69 wt % SiO₂) were added in parallel to the boiling dispersion under agitation over a period of about two hours.

The resulting reaction mixture was kept agitated for a further 30 min and allowed to cool to room temperature while being agitated, yielding 1863 g of intermediate aqueous dispersion (IM-07) of 31.4 wt % of silica particles with aluminate-comprising shell having an average diameter of 35.75 nm. Further properties of the intermediate aqueous dispersion (IM-07) are indicated in Table 3 below.

The so-obtained intermediate aqueous dispersion (IM-07) of silica particles with aluminate-comprising shell was passed through a column of cation exchange resin, and 1647.5 g of aqueous dispersion of 30.6 wt % of silica particles with an aluminate-comprising shell and having a pH of between 2 and 3 were recovered, and subsequently further diluted with de-ionized water to a total of 1680.5 g of aqueous dispersion (D-07) of 30 wt % of silica particles. Properties of the resulting aqueous dispersion (D-07) are given in Table 4 below.

### Example 8

1800 g of an aqueous dispersion of 33.6 wt % of silica particles having an average particle diameter of 35 nm and a specific surface area of 74.4 m²/g with a pH of 9.2 were heated to boiling. Then 5.254 g of sodium aluminate in 287.7 g of water and 676.7 g of aqueous silicic acid solution (5.87 wt % SiO₂) were added in parallel to the boiling dispersion under agitation over a period of about two hours.

The resulting reaction mixture was continued to be agitated for a further 30 min and allowed to cool to room temperature while being agitated, yielding 1973 g of intermediate aqueous dispersion (IM-08) of 31.2 wt % of silica particles with aluminate-comprising shell having a diameter of 35.75 nm. Further properties of the intermediate aqueous dispersion (IM-08) are indicated in Table 3 below.

The so-obtained intermediate aqueous dispersion (IM-08) of silica particles with aluminate-comprising shell was then passed through a column of cation exchange resin, and 1762.8 g of aqueous dispersion of 30.4 wt % of silica particle with aluminate-comprising shell and a pH of 2 to 3 were recovered and subsequently further diluted with de-ionized water to a total of 1786.4 g of aqueous dispersion (D-08) of 30 wt % of silica particles with an aluminate-comprising shell. Properties of the resulting aqueous dispersion (D-08) are given in Table 4 below.

TABLE 3
Properties of the intermediate dispersions
(measured at 30 wt % SiO₂)

| | | IM-05 | IM-06 | IM-07 | IM-08 |
|---|---|---|---|---|---|
| SiO₂ content | [wt %] | 30.0 | 30.0 | 30.0 | 30.0 |
| Average particle | [nm] | 35.75 | 35.75 | 35.75 | 35.75 |
| diameter | | | | | |
| pH (at 20° C.) | | 9.03 | 9.80 | 9.57 | 10.00 |
| Zeta potential | [mV] | −31.9 | −31.4 | −33.8 | −35.7 |
| Al content (ICP-OES) | [ppm] | 87 | 500 | 556 | 999 |

TABLE 4
Properties of the aqueous dispersions (measured at 30 wt % SiO₂)

| | | D-05 | D-06 | D-07 | D-08 |
|---|---|---|---|---|---|
| SiO₂ content | [wt %] | 30.0 | 29.7 | 30.0 | 30.0 |
| Average particle | [nm] | 35.75 | 35.75 | 35.75 | 35.75 |
| diameter | | | | | |
| pH (at 20° C.) | | 2.13 | 2.42 | 2.28 | 2.44 |
| Zeta potential | [mV] | −4.7 | −7.3 | −11.5 | −8.6 |
| Al content (ICP-OES) | [ppm] | 84 | 171 | 313 | 442 |

### Example 9

Chemical mechanical polishing was performed using the aqueous compositions D-05, D-06, D-07, and D-08, without any further additives-Before use in chemical mechanical polishing the compositions may be filtered (0.3 μm pore size).

Polishing was then performed on a Bruker CP-4 (available from Bruker Corporation, Billerica, MA, USA) using an IC1000™ CMP polishing pad (available from DuPont de Nemours, Wilmington, Delaware, USA) on 4″ silicon nitride wafers. Further polishing conditions were as indicated in the following Table 5.

TABLE 5

| Flow rate | 80 | ml/min |
|---|---|---|
| Polishing time | 1 | min |
| Dynamic force | 5 psi as down force | |
| Platen speed (PS) | 115 | rpm |
| Head speed (HS) | 90 | rpm |

| | |
|---|---|
| Pad conditioner | A165-CIP1 (4.25″, 3M) |

Results of the chemical-mechanical polishing were as shown in Table 6 below, wherein examples PC-1 and PC-2 are comparative.

TABLE 6

Removal rate silicon nitride
[A/min]

| Reference | Silica | by weighing | by ellipsometry |
|---|---|---|---|
| PC-1 | D-05 | 752 | 819 |
| PC-2 | D-06 | 697 | 700 |
| P-1 | D-07 | 680 | 714 |
| P-2 | D-08 | 511 | 588 |

The data clearly show that the addition of an aluminate-comprising shell to silica particles allows modifying the removal rates for—in this case—silicon nitride over a wide range, which subsequently will also help in controlling the removal rate selectivity of the present aluminate-comprising silica particles.

Thus, in general it has surprisingly been found that the present aluminate-comprising silica particles allow modifying the zeta potential over a very wide range, particularly for anionic silica particles. It is therefore expected—and has already been shown for silicon nitride—that the present approach also allows for modification of the respective removal rates for a number of different substrates over a wide range of materials. The chemical-mechanical polishing experiments conducted herein have also shown the general suitability of the present compositions for chemical-mechanical polishing in the semiconductor industry.

1. Composition comprising water and core-shell silica particles, wherein the composition is acidic, and the core-shell silica particles comprise a core and a shell, said shell comprising aluminate moieties internal to an outer surface of the silica particles.

2. Composition according to claim 1, wherein the composition has a pH of at least 1.5 and of at most 5.5.

3. Composition according to claim 1, wherein the aluminate-comprising shell has a thickness of at least 0.10 nm and of at most 2.0 nm.

4. Composition according to claim 1, wherein the amount of aluminium comprised in the aluminate-comprising phase is at least 500 ppm and at most 25,000 ppm, with ppm relative to the respective weight of the aluminate-comprising shell.

5. Composition according to claim 1, wherein the composition has a zeta potential of at most 0 mV and of at least −30 mV, determined by electrophoretic light scattering for a composition comprising 15 wt % of silica particles, with wt % relative to the total weight of the composition.

6. Composition according to claim 1, wherein the core-shell silica particles are comprised in the composition in at least 0.1 wt % and in at most 50 wt %, with wt % being relative to the total weight of the composition.

7. Composition according to claim 1, wherein the silica particles comprise an alkoxy organosilane on the surface.

8. Composition according to claim 1, wherein the composition comprises any one or more of the group consisting of biocide, pH-adjusting agent, pH-buffering agent, oxidizer, chelating agent, corrosion inhibitor, and surfactant.

9. Method for producing a composition comprising water and core-shell silica particles, the method comprising the steps of
(a) providing silica particles;
(b) providing an aqueous solution of silicic acid and providing an aqueous solution of sodium aluminate, and reacting in presence of the silica particles provided in the preceding step the silicic acid and the sodium aluminate under alkaline conditions and at a temperature of at least 40° C., to form a shell onto said silica particles, thereby producing core-shell silica particles; and
(c) passing the core-shell silica particles produced in the preceding step through a column of cation exchange resin,
thereby obtaining an acidic composition comprising water and core-shell silica particles, the core-shell silica particles comprising a core and a shell, said shell comprising aluminate moieties internal to an outer surface of the silica particles.

10. The method according to claim 9, the method comprising the step of
(d) providing an alkoxy organosilane; and
(e) bringing the silica particles obtained in step (b) and the alkoxy organosilane into contact with each other, thereby obtaining modified silica particles comprising aluminate moieties internal to an outer surface of the silica particles.

11. A method for chemical mechanical polishing comprising the steps of
(A) providing a substrate to be polished;
(B) providing the composition of claim 1,
(C) providing a chemical mechanical polishing pad with a polishing surface;
(D) bringing the polishing surface of the chemical mechanical polishing pad into contact with the substrate; and
(E) polishing the substrate such that at least a part of the substrate is removed.

12. Method according to claim 11, wherein the substrate provided in step (A) comprises
(i) at least one layer comprising, preferably essentially consisting of, silicon oxide, or at least one layer comprising, preferably essentially consisting of, silicon nitride; and
(ii) at least one layer comprising, preferably essentially consisting of, one or more metal or metal alloy.

13. Method according to claim 11, wherein
(i) the silicon oxide is selected from the group consisting of borophosphosilicate glass (BPSG), plasma-enhanced tetraethyl ortho silicate (PETEOS), thermal oxide, undoped silicate glass, high density plasma (HDP) oxide, and silane oxide; and/or
(ii) the one or more metal or metal alloy is selected from the group consisting of tungsten, tantalum, copper, titanium, titanium nitride, aluminum silicon, and any combination of any of these, and preferably is tungsten.

14. Method according to claim 11, wherein the substrate is selected from the group consisting of flat panel displays, integrated circuits (ICs), memory or rigid disks, metals, interlayer dielectric devices (ILDs), semiconductors, micro-electro-mechanical systems, ferroelectrics, and magnetic heads.
